(19) United States
(12) Patent Application Publication
(10) Pub. No.: US 2026/0271510 A1
(43) Pub. Date: Sep. 10, 2026

(54) Display Panel And Electronic Device Including The Same

(71) Applicant: Samsung Display Co., Ltd., Yongin-si (KR)

(72) Inventors: Dongchan Kim, Yongin-si (KR); Seongheun Kim, Yongin-si (KR); Wonjong Kim, Yongin-si (KR); Sungsoo Bae, Yongin-si (KR); Byeongwook Yoo, Yongin-si (KR); Youngeun Choi, Yongin-si (KR); Jiyong Choi, Yongin-si (KR)

(73) Assignee: Samsung Display Co., Ltd., Yongin-si (KR)

(21) Appl. No.: 19/556,623

(22) Filed: Mar. 4, 2026

(30) Foreign Application Priority Data
Mar. 4, 2025 (KR) 10-2025-0027671

(51) Int. Cl. H10K 50/17; H10K 59/80; H10K 102/00

(52) U.S. Cl. CPC H10K 50/171; H10K 59/805; H10K 2102/351

(57) ABSTRACT

A display panel may include a substrate; a pixel electrode disposed on the substrate; an electron injection layer disposed on the pixel electrode, the electron injection layer including silver (Ag) and lithium (Li); and a counter electrode disposed on the electron injection layer. A concentration of the lithium (Li) included in the electron injection layer is 5 vol% or more and 20 vol% or less.

### CROSS-REFERENCE TO RELATED APPLICATION

This application claims priority under 35 U.S.C. §119 to Korean Patent Application No. 10-2025-0027671, filed on Mar. 4, 2025, in the Korean Intellectual Property Office, the disclosure of which is incorporated by reference herein in its entirety.

### TECHNICAL FIELD

One or more aspects of the present disclosure relate to a display panel and an electronic device including the same.

### BACKGROUND

A display device visually displays data. The display device may provide images using light-emitting diodes. Display devices are becoming more diverse in their uses, and various designs are being attempted to improve the quality of display devices.

### SUMMARY

One or more aspects of the present disclosure include a display panel and an electronic device including the same.

Additional aspects will be set forth in part in the description which follows and, in part, will be apparent from the description, or may be learned by practice of the presented aspects of the disclosure.

According to one or more aspects, a display panel comprises a substrate, a pixel electrode disposed on the substrate, an electron injection layer disposed on the pixel electrode and including silver (Ag) and lithium (Li) and a counter electrode disposed on the electron injection layer, wherein a concentration of the lithium (Li) included in the electron injection layer is 5 vol% or more and 20 vol% or less.

According to the present aspect, a thickness of the electron injection layer may be 5 Å or more and 100 Å or less.

According to the present aspect, the counter electrode may include silver (Ag).

According to the present aspect, a thickness of the counter electrode may be 50 Å or more and 200 Å or less.

According to the present aspect, the counter electrode may include a silver (Ag)-based alloy.

According to the present aspect, the counter electrode may include silver (Ag), palladium (Pd), and copper (Cu).

According to the present aspect, the thickness of the counter electrode may be 50 Å or more and 200 Å or less.

According to the present aspect, the counter electrode may include a conductive oxide.

According to the present aspect, the counter electrode may include at least one of indium tin oxide (ITO), indium zinc oxide (IZO), indium gallium oxide (IGO), or indium gallium zinc oxide (IGZO).

According to the present aspect, the thickness of the counter electrode may be 100 Å or more and 5000 Å or less.

According to one or more aspects, an electronic device comprises a display panel and a lower cover having an opening exposing a part of the display panel on a front surface, wherein the display panel comprises a substrate, and a pixel electrode disposed on the substrate, an electron injection layer disposed on the pixel electrode and including silver (Ag) and lithium (Li) and a counter electrode disposed on the electron injection layer, wherein the electron injection layer includes silver (Ag) and lithium (Li), and a concentration of the lithium (Li) included in the electron injection layer is 5 vol% or more and 20 vol% or less.

According to the present aspect, the device may further include a hole injection layer disposed on the pixel electrode and an intermediate layer disposed on the hole injection layer.

According to the present aspect, the intermediate layer may include a plurality of stacks, and each of the plurality of stacks may include a hole transport layer, an emitting layer, and an electron transport layer.

According to the present aspect, a thickness of the electron injection layer may be 5 Å or more and 100 Å or less.

According to the present aspect, the counter electrode may include silver (Ag).

According to the present aspect, a thickness of the counter electrode may be 50 Å or more and 200 Å or less.

According to the present aspect, the counter electrode may include a silver (Ag)-based alloy, and the thickness of the counter electrode may be 50 Å or more and 200 Å or less.

According to the present aspect, the counter electrode may include silver (Ag), palladium (Pd), and copper (Cu).

According to the present aspect, the counter electrode may include a conductive oxide, and the thickness of the counter electrode may be 100 Å or more and 5000 Å or less.

According to the present aspect, the counter electrode may include at least one of indium tin oxide (ITO), indium zinc oxide (IZO), indium gallium oxide (IGO), or indium gallium zinc oxide (IGZO).

### BRIEF DESCRIPTION OF THE DRAWINGS

The above and other features and advantages of certain aspects of the disclosure will be more apparent from the following description taken in conjunction with the accompanying drawings, in which:

FIGS. 1A and 1B are respectively schematic perspective views of a display device according to an aspect;

FIG. 2 is a block diagram of a central processing unit according to an aspect;

FIG. 3 is a schematic diagram of an electronic device according to various aspects;

FIGS. 4A and 4B are schematic circuit diagrams of a light-emitting diode corresponding to one subpixel of a display device, according to an aspect, and a subpixel circuit electrically connected to the light-emitting diode;

FIG. 5 is a schematic cross-sectional view of a display panel according to an aspect;

FIG. 6 is a schematic cross-sectional view of a display panel according to an aspect;

FIG. 7 is a schematic cross-sectional view of a middle layer of an organic light-emitting diode having a tandem structure;

FIG. 8 is a graph comparing the light absorption rate according to the concentration of lithium (Li) when the electron injection layer includes silver (Ag) and lithium (Li), with the light absorption rate when the electron injection layer includes ytterbium (Yb);

FIG. 9 is a graph comparing a work function according to a concentration of lithium (Li) when the electron injection layer includes silver (Ag) and lithium (Li) with a work function when the electron injection layer includes ytterbium (Yb);

FIG. 10 is a graph comparing the sheet resistance according to the concentration of lithium (Li) when the electron injection layer includes silver (Ag) and lithium (Li), with the sheet resistance when the electron injection layer includes ytterbium (Yb); and

FIG. 11 is a graph of the luminance of a display device over time when the electron injection layer includes ytterbium (Yb) and when the electron injection layer includes silver (Ag) and lithium (Li) at different concentrations.

### DETAILED DESCRIPTION

The present disclosure may have various aspects, which may undergo various modifications, and specific aspects are illustrated in the drawings and described in detail in the detailed description. The effects and features of the aspects of the present disclosure and the method for achieving them will become clear with reference to the aspects described in detail below together with the drawings. However, the disclosure is not limited to the aspects disclosed below and may be implemented in various forms.

Hereinafter, aspects of the disclosure will be described in detail with reference to the attached drawings. When describing with reference to the drawings, identical or corresponding components are given the same drawing reference numerals and redundant descriptions thereof will be omitted.

In the description below, the terms first, second, etc. are not used in a limiting sense but are used for the purpose of distinguishing one component from another.

In the description below, singular expressions include plural expressions unless the context clearly indicates otherwise.

In the description below, terms such as “include” or “have” mean that a feature or component described in the specification is present, and do not exclude in advance the possibility that one or more other features or components may be added.

In the following description, when a part such as a film, region, component, etc. is said to be on or above another part, it includes not only the case where it is directly on top of the other part, but also the case where another film, region, component, etc. is interposed in between.

In the drawings, components may be exaggerated or reduced in size for convenience of explanation. For example, the size and thickness of each component shown in the drawing are arbitrarily shown for convenience of explanation, and thus the disclosure is not necessarily limited to what is shown.

In some aspects, where the implementation is otherwise feasible, specific process sequences may be performed in a different order than described. For example, two processes described sequentially may be performed substantially simultaneously, or may proceed in the reverse order from that described.

In this specification, “A and/or B” refers to either A, B, or both A and B. And, “at least one of A and B” indicates the case where it is A, or B, or both A and B.

In the following description, when it is said that a film, region, component, etc. are connected, it includes a case where the films, regions, or components are directly connected, and/or a case where other films, regions, or components are interposed between the films, regions, or components and are indirectly connected. For example, when it is said in this specification that a film, region, component, etc. are electrically connected, it refers to a case where the film, region, component, etc. are directly electrically connected, and/or a case where another film, region, component, etc. is interposed between them and is indirectly electrically connected.

The x-axis, y-axis, and z-axis are not limited to the three axes on the orthogonal coordinate system, and can be interpreted in a broad sense that includes them. For example, the x-axis, y-axis, and z-axis may be orthogonal to each other, but they may also refer to different directions that are not orthogonal to each other.

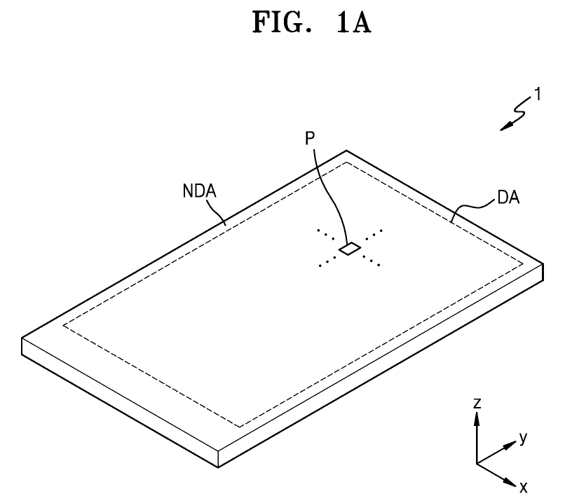

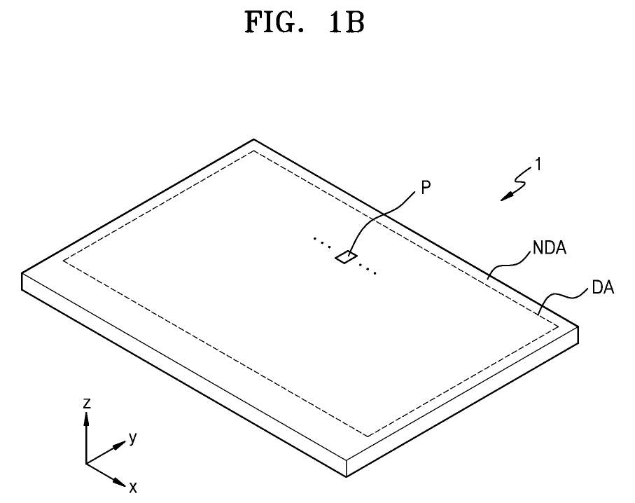

FIGS. 1A and 1B are perspective views schematically illustrating a display device according to an aspect, respectively.

Referring to FIGS. 1A and 1B, a display device 1 may include a display area DA and a non-display area NDA arranged outside the display area DA. The display area DA may display an image through subpixels P arranged in the display area DA. The non-display area NDA is located outside the display area DA and is non-display area that does not display images, and may completely surround the display area DA. Drivers, etc. for providing electrical signals or power to the display area DA may be located in the non-display area NDA. Pads, to which electronic components or printed circuit boards may be electrically connected, may be located in the non-display area NDA.

As an example, FIG. 1A illustrates that the display area DA is a polygon (e.g., a square) of which x-direction length is smaller than its y-direction length however, as another example, FIG. 1B illustrates that the display area (DA) may be a polygon (e.g., a square) of which y-direction length is smaller than its x-direction length. Although FIG. 1A and FIG. 1B illustrate that the display area DA is approximately rectangular, the disclosure is not limited thereto. As another aspect, the display area DA may have various shapes such as an N-gon (N is a natural number greater than or equal to 3), a circle, or an ellipse. FIG. 1A and FIG. 1B illustrate that the corners of the display area DA have a shape including vertices where straight lines meet, but as another aspect, the display area DA may be a polygon with rounded corners.

For convenience of explanation, the following description will be made on the case where the display device 1 is an electronic device such as a smart phone, but the display device 1 of the disclosure is not limited thereto. The display device 1 may be applied to various products such as portable electronic devices such as mobile phones, smart phones, tablet personal computers, mobile communication terminals, electronic notebooks, electronic books, portable multimedia players (PMPs), navigation devices, or Ultra Mobile PCs (UMPCs), as well as televisions, laptops, monitors, billboards, or Internet of Things (IOT). In addition, the display device 1 according to an aspect may be applied to wearable devices such as a smart watch, a watch phone, a glasses-type display, or a head mounted display (HMD). In addition, the display device 1 according to an aspect may be applied to a dashboard of a car, a CID (Center Information Display) placed on a center fascia or dashboard of a car, a room mirror display replacing a side mirror of a car, and a display screen placed on the back of a front seat as entertainment for the rear seat of a car.

The display device according to the aspect may be applied to various electronic devices. An electronic device according to an aspect includes the display device described above, and may further include a module or device having additional functions in addition to the display device.

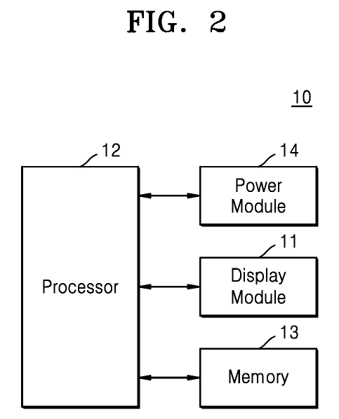

FIG. 2 is a block diagram of a central processing unit according to an aspect. Referring to FIG. 2, an electronic device 10 according to an aspect may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for the operation of the processor 12 or the display module 11 may be stored in the memory 13. When the processor 12 may execute an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 10.

At least one of the components of the above-described electronic device may be included in the display device according to the above-described aspects. Additionally, some of the individual modules functionally included within a module may be included within the display device, while others may be provided separately from the display device. For example, the display device may include the display module 11, and the processor 12, the memory 13 and the power module 14 may be provided in the form of other devices within the electronic device other than the display device.

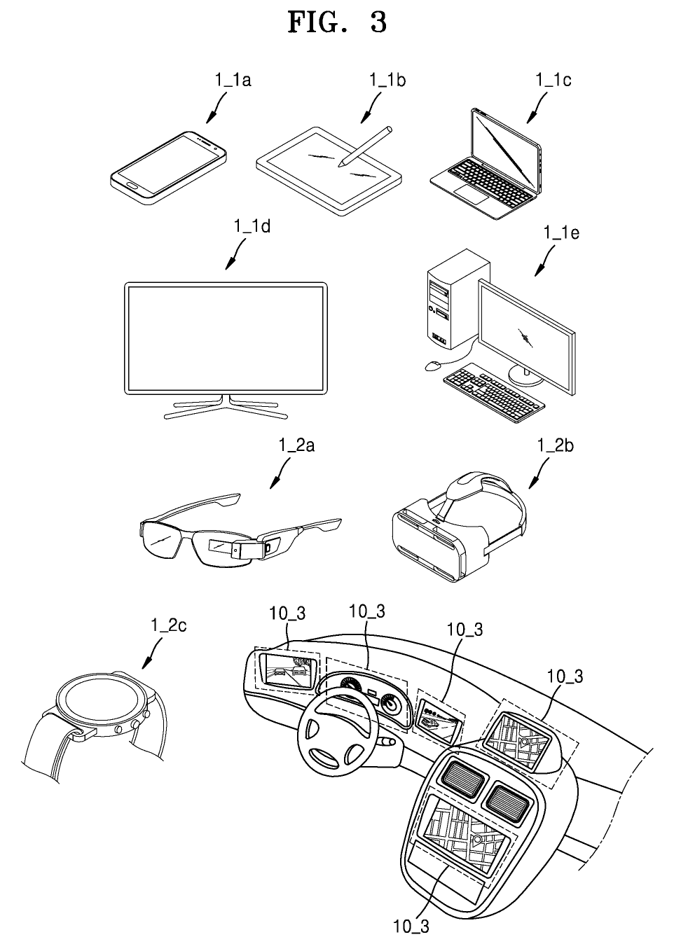

FIG. 3 is a schematic diagram of an electronic device according to various aspects.

Referring to FIG. 3, various electronic devices to which display devices according to aspects are applied may include not only image display electronic devices such as a smart phone 10_1a, a tablet PC 10_1b, a laptop 10_1c, a TV 10_1d, or a desk monitor 10_1e, but also wearable electronic devices including display modules such as smart glasses 10_2a, a head mounted display 10_2b, or a smart watch 10_2c, or vehicle electronic devices 10_3 including display modules such as a CID (Center Information Display) or a room mirror display arranged on a dashboard, center fascia, or dashboard of an automobile.

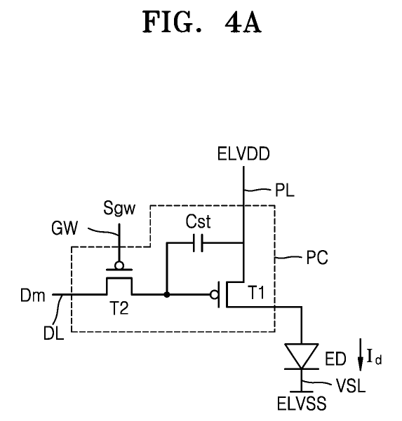

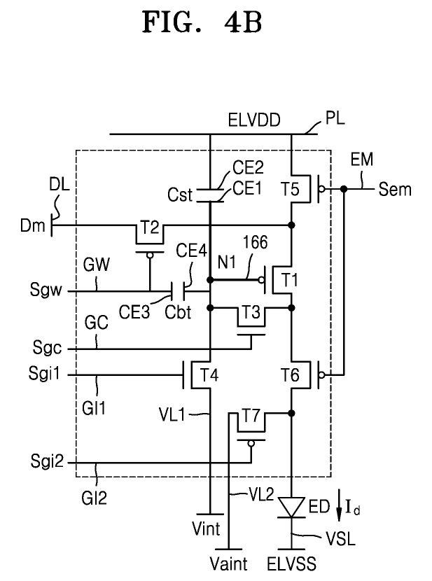

FIGS. 4A and 4B are equivalent circuit diagrams schematically showing a light-emitting diode corresponding to one subpixel of a display device according to an aspect and a subpixel circuit electrically connected to the light-emitting diode.

Referring to FIG. 4A, a light emitting diode ED is electrically connected to a subpixel circuit PC, and the subpixel circuit PC may include a first transistor T1, a second transistor T2, and a storage capacitor Cst. A subpixel electrode (e.g., an anode) of the light-emitting diode ED may be electrically connected to the first transistor T1, and a counter electrode (e.g., a cathode) can be electrically connected to an auxiliary wiring VSL, and a voltage corresponding to a common voltage ELVSS may be transmitted through the auxiliary wiring VSL.

The second transistor T2 may transmit a data signal Dm input through a data line DL to the first transistor T1 according to a scan signal Sgw input through a scan line GW.

The storage capacitor Cst may be connected to the second transistor T2 and a driving voltage line PL, and may store a voltage corresponding to the difference between the voltage received from the second transistor T2 and a driving voltage ELVDD supplied to the driving voltage line PL.

The first transistor T1 may be connected to a driving voltage line PL and the storage capacitor Cst, and may control a driving current Id flowing from the driving voltage line PL to the light-emitting diode ED in response to a voltage value stored in the storage capacitor Cst. The light-emitting diode ED may emit light with a predetermined brightness depending on the driving current Id.

FIG. 4A illustrates a case where the subpixel circuit PC includes two transistors and one storage thin film transistor, but the present disclosure is not limited thereto.

FIG. 4B is an equivalent circuit diagram schematically showing a light-emitting diode corresponding to one subpixel of a display device according to another aspect and a subpixel circuit electrically connected to the light-emitting diode.

Referring to FIG. 4B, a subpixel circuit PC may include seven transistors and two capacitors.

The subpixel circuit PC may include a first to seventh transistors T1, T2, T3, T4, T5, T6, T7, a storage capacitor Cst, and a boost capacitor Cbt. As another aspect, the subpixel circuit PC may not include the boost capacitor Cbt. A subpixel electrode (e.g., an anode) of a light-emitting diode ED may be electrically connected to the first transistor T1 via the sixth transistor T6, and a counter electrode (e.g., a cathode) may be electrically connected to an auxiliary wire VSL, and a voltage corresponding to a common voltage ELVSS may be transmitted through an auxiliary wire VSL.

Some of the first to seventh transistors T1, T2, T3, T4, T5, T6, T7 may be NMOS (n-channel MOSFETs), and the rest may be PMOS (p-channel MOSFETs). As an example, the third and fourth transistors T3, T4 may be NMOS (n-channel MOSFETs) and the rest may be PMOS (p-channel MOSFETs), as shown in FIG. 2b. For example, the third and fourth transistors T3, T4 may be NMOS (n-channel MOSFETs) including oxide-based semiconductor materials, and the rest may be PMOS (p-channel MOSFETs) including silicon-based semiconductor materials. In another aspect, the third, fourth, and seventh transistors T3, T4, T7 may be NMOS (n-channel MOSFETs), and the rest may be PMOS (p-channel MOSFETs).

The first to seventh transistors T1, T2, T3, T4, T5, T6, T7, the storage capacitor Cst, and the boost capacitor Cbt may be connected to the signal line. The signal lines may include a scan line GW, an emission control line EM, a compensation gate line GC, a first initialization gate line GI1, a second initialization gate line GI2, and a data line DL. The subpixel circuit PC may be electrically connected to voltage lines, such as a driving voltage line PL, a first initialization voltage line VL1, and a second initialization voltage line VL2.

The first transistor T1 may be a driving transistor. A first gate electrode of the first transistor T1 is connected to the storage capacitor Cst, a first electrode of the first transistor T1 may be electrically connected to the driving voltage line PL via the fifth transistor T5, and a second electrode of the first transistor T1 may be electrically connected to a first electrode (e.g., an anode) of the light-emitting diode ED via the sixth transistor T6. One of the first electrode and the second electrode of the first transistor T1 may be a source electrode and the other may be a drain electrode. The first transistor T1 may supply the driving current Id to the light-emitting diode ED according to the switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be connected to the first driving electrode of the first transistor T1 and may be electrically connected to the driving voltage line PL via the fifth transistor T5. One of the first electrode and the second electrode of the second transistor T2 may be a source electrode and the other may be a drain electrode. The second transistor T2 may be turned on according to a scan signal Sgw transmitted through the scan line GW and perform a switching operation to transmit a data signal Dm transmitted through the data line DL to the first electrode of the first transistor T1.

The third transistor T3 may be a compensation transistor that compensates for the threshold voltage of the first transistor T1. A third gate electrode of the third transistor T3 may be connected to the compensation gate line GC. A first electrode of the third transistor T3 may be connected to a lower electrode CE1 of the storage capacitor Cst and the first gate electrode of the first transistor T1 through the node connection line 166. The first electrode of the third transistor T3 may be connected to the fourth transistor T4. A second electrode of the third transistor T3 may be connected to the second electrode of the first transistor T1 and may be electrically connected to the first electrode (e.g., anode) of the light-emitting diode ED via the sixth transistor T6. One of the first electrode and the second electrode of the third transistor T3 may be a source electrode and the other may be a drain electrode.

The third transistor T3 may be turned on according to a compensation signal Sgc received through the compensation gate line GC to electrically connect the first gate electrode and the second electrode (e.g., drain electrode) of the first transistor T1 to diode-connect the first transistor T1.

The fourth transistor T4 may be a first initialization transistor that initializes the first gate electrode of the first transistor T1. A fourth gate electrode of the fourth transistor T4 may be connected to the first initialization gate line GI1. A first electrode of the fourth transistor T4 may be connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode and the other may be a drain electrode. The fourth transistor T4 may be turned on according to a first initialization signal Sgi1 received through the first initialization gate line GI1 to transmit the first initialization voltage Vint to the first gate electrode of the first transistor T1 to perform an initialization operation of initializing the voltage of the first gate electrode of the first transistor T1.

The fifth transistor T5 may be a motion control transistor. A fifth gate electrode of the fifth transistor T5 may be connected to the emission control line EM, a first electrode of the fifth transistor T5 may be connected to the driving voltage line PL, and a second electrode of the fifth transistor T5 may be connected to the first driving electrode of the first transistor T1 and the second electrode of the second transistor T2. One of the first electrode and the second electrode of the fifth transistor T5 may be a source electrode and the other may be a drain electrode.

The sixth transistor T6 may be a light-emitting control transistor. The sixth gate electrode of the sixth transistor T6 may be connected to the emission control line EM, a first electrode of the sixth transistor T6 is connected to a second electrode of the first transistor T1 and the second electrode of the third transistor T3, and the second electrode of the sixth transistor T6 may be electrically connected to a second electrode of the seventh transistor T7 and the first electrode (e.g., anode) of the light-emitting diode ED. One of the first electrode and the second electrode of the sixth transistor T6 may be a source electrode and the other may be a drain electrode.

The fifth transistor T5 and the sixth transistor T6 may be simultaneously turned on according to a light emission control signal Sem received through the light emission control line EM, so that a driving voltage ELVDD may be transmitted to the light emitting diode ED and the driving current Id may flow to the light emitting diode ED.

The seventh transistor T7 may be a second initialization transistor that initializes the first electrode (e.g., anode) of the light emitting diode ED. A seventh gate electrode of the seventh transistor T7 may be connected to the second initialization gate line GI2. A first electrode of the seventh transistor T7 may be connected to the second initialization voltage line VL2. A second electrode of the seventh transistor T7 may be connected to the second electrode of the sixth transistor T6 and the first electrode (e.g., anode) of the light-emitting diode ED. The seventh transistor T7 may be turned on according to a second initialization signal Sgi2 transmitted through the second initialization gate line GI2 to transmit the second initialization voltage Vaint to the first electrode (e.g., anode) of the light-emitting diode ED, thereby initializing the first electrode of the light-emitting diode ED.

In some aspects, the second initialization voltage line VL2 may then be a scan line. For example, the second initialization gate line GI2 connected to the seventh transistor T7 of the subpixel circuit PC arranged in the i-th row (i is a natural number) may correspond to the scan line of the subpixel circuit PC arranged in the (i+1)-th row. In another aspect, the second initialization voltage line VL2 may be the emission control line EM. For example, the emission control line EM may be electrically connected to the fifth to seventh transistors T5, T6, T7.

The storage capacitor Cst may include the lower electrode CE1 and an upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may store a charge corresponding to the difference between the voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW , and the fourth electrode CE4 may be connected to the first electrode of the third transistor T3 and the node connection line 166 . The boost capacitor Cbt may increase the voltage of a first node N1 when the scan signal Sgw supplied to the scan line GW is turned off, and when the voltage of the first node N1 increases, the black gradation may be expressed clearly.

The first node N1 may be a region where the first gate electrode of the first transistor T1, the first electrode of the third transistor T3, the second electrode of the fourth transistor T4, and the fourth electrode CE4 of the boost capacitor Cbt are connected.

In an aspect, FIG. 4B illustrates that the third and fourth transistors T3, T4 are NMOS (n-channel MOSFETs), and the first, second, fifth to seventh transistors T1, T2, T5, T6, T7 are PMOS (p-channel MOSFETs). In the case of the first transistor T1 that directly affects the brightness of the display device that displays an image, a semiconductor layer made of polycrystalline silicon with high reliability may be configured to be included, thereby enabling the implementation of a high-resolution display device.

Although FIG. 4B illustrates that some of the transistors may be NMOSFETs and the rest may be PMOSFETs, the disclosure is not limited thereto. In another aspect, the subpixel circuit PC may be varied to include three transistors, such as all three transistors being NMOSFETs.

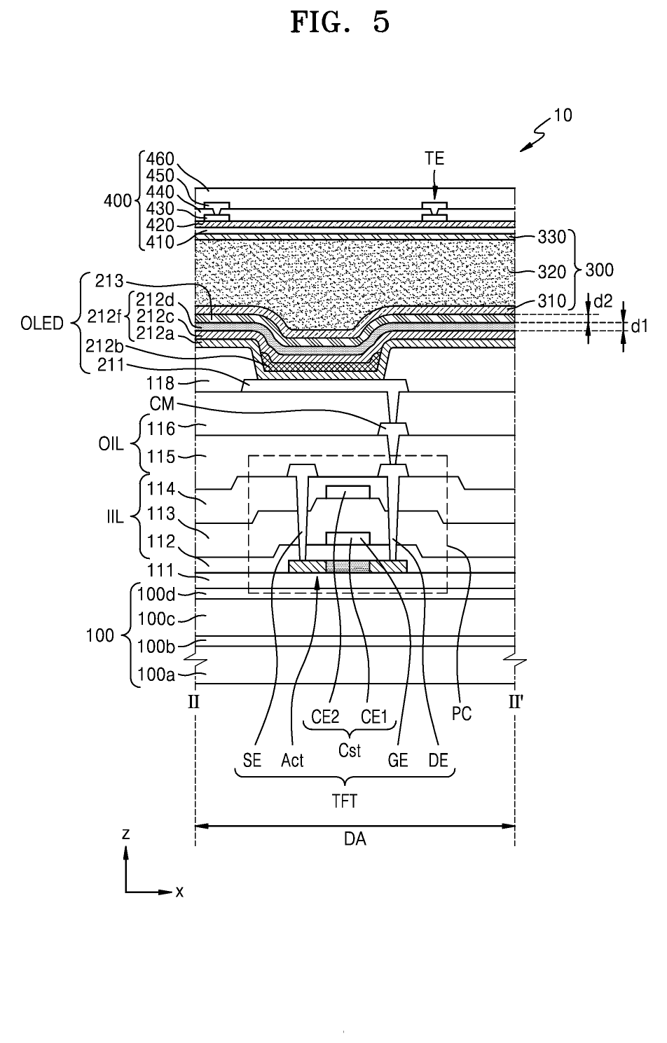

FIG. 5 is a cross-sectional view schematically illustrating a display panel according to an aspect.

Referring to FIG. 5, a display panel 10 may include a substrate 100, an inorganic insulating layer IIL, an organic insulating layer OIL, a subpixel circuit PC, a connection electrode CM, an organic light-emitting diode OLED, a pixel definition film 118, a thin film encapsulation layer 300, and a touch sensor layer 400. That is, the substrate 100, the inorganic insulating layer IIL, the organic insulating layer OIL, the subpixel circuit PC, the connection electrode CM, the organic light-emitting diode OLED, the pixel definition film 118, the thin film encapsulation layer 300, and the touch sensor layer 400 may be arranged on a display area DA of the display panel 10.

The substrate 100 may include a first base layer 100a, a first barrier layer 100b, a second base layer 100c, and a second barrier layer 100d. In an aspect, the first base layer 100a, the first barrier layer 100b, the second base layer 100c, and the second barrier layer 100d may be sequentially laminated in the thickness direction of the substrate 100.

At least one of the first base layer 100a and the second base layer 100c may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

The first barrier layer 100b and the second barrier layer 100d are barrier layers that prevent the penetration of external foreign substances, and may be a single layer or multiple layers including inorganic materials such as silicon nitride (SiN_{X}), silicon oxide (SiO₂), or silicon oxynitride (SiON).

A buffer layer 111 may be disposed on the substrate 100. The buffer layer 111 may include an inorganic insulator such as silicon nitride (SiNX), silicon oxynitride (SiON), or silicon oxide (SiO₂), and may be a single layer or multilayer including the aforementioned inorganic insulator.

The inorganic insulating layer IIL may be disposed on the buffer layer 111. The inorganic insulating layer IIL may include a first inorganic insulating layer 112, a second inorganic insulating layer 113, and a third inorganic insulating layer 114.

The subpixel circuit PC may be placed in the display area DA. The subpixel circuit PC may include a thin film transistor TFT and a storage capacitor Cst. The thin film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. Alternatively, the semiconductor layer Act may include amorphous silicon, an oxide semiconductor, an organic semiconductor, etc. The semiconductor layer Act may include a channel region and a drain region and a source region respectively disposed on both sides of the channel region.

The gate electrode GE may be disposed on the semiconductor layer Act. The gate electrode GE may overlap the channel region. The gate electrode GE may include a low-resistance metal material. The gate electrode GE may include a conductive material including molybdenum (Mo), aluminum (Al), copper (Cu), titanium (Ti), etc., and may be formed as a multilayer or single layer including the aforementioned materials.

The first inorganic insulating layer 112 may be disposed between the semiconductor layer Act and the gate electrode GE. The first inorganic insulating layer 112 may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO). The second inorganic insulating layer 113 may be disposed on the gate electrode GE. The second insulating layer 113 may be disposed to cover the gate electrode GE. The second inorganic insulating layer 113 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode CE2 of the storage capacitor Cst may be placed on the second inorganic insulating layer 113. The upper electrode CE2 may overlap with the gate electrode GE disposed underneath it. At this time, the gate electrode GE and the upper electrode CE2, which overlap with the second inorganic insulating layer 113 in between, may form the storage capacitor Cst. That is, the gate electrode GE may function as a lower electrode CE1 of the storage capacitor Cst.

In this way, the storage capacitor Cst and the thin film transistor TFT may be formed by overlapping each other. However, the disclosure is not limited thereto. For example, the storage capacitor Cst may be formed so as not to overlap with the thin film transistor TFT. That is, the lower electrode CE1 of the storage capacitor Cst may be provided as a separate component from the gate electrode GE of the thin film transistor TFT and spaced apart from the gate electrode GE of the thin film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may be a single layer or multiple layers of the aforementioned materials.

The third inorganic insulating layer 114 may be disposed on the upper electrode CE2. The third insulating layer 114 may cover the upper electrode CE2. The third inorganic insulating layer 114 may include silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnO). The third inorganic insulating layer 114 may be a single layer or multiple layers including the aforementioned inorganic insulating material.

The drain electrode DE and the source electrode SE may each be disposed on the third inorganic insulating layer 114. The drain electrode DE and the source electrode SE may be connected to the semiconductor layer Act through contact holes provided in the first inorganic insulating layer 112, the second inorganic insulating layer 113, and the third inorganic insulating layer 114, respectively. The drain electrode DE and source electrode SE may include a material having good conductivity. The drain electrode DE and the source electrode SE may include a conductive material including molybdenum (Mo), aluminum (Al), copper (Cu), titanium (Ti), etc., and may be formed as a multilayer or single layer including the above-mentioned materials. For example, the drain electrode DE and the source electrode SE may have a multilayer structure of Ti/Al/Ti.

The organic insulating layer OIL may be disposed on the inorganic insulating layer IIL. The organic insulating layer OIL may include a first organic insulating layer 115 and a second organic insulating layer 116. Although FIG. 3 illustrates that there are two organic insulating layers OIL, the disclosure is not limited thereto. The organic insulating layers OIL may be provided in one, three or four layers.

The first organic insulating layer 115 may cover the drain electrode DE and the source electrode SE. The first organic insulating layer 115 may include an organic insulating material such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, or a blend thereof.

The connection electrode CM may be disposed on the first organic insulating layer 115. At this time, the connection electrode CM may be connected to the drain electrode DE or the source electrode SE through the contact hole of the first organic insulating layer 115. The connection electrode CM may include a material having good conductivity. The connection electrode CM may include a conductive material including molybdenum (Mo), aluminum (Al), copper (Cu), titanium (Ti), etc., and may be formed as a multilayer or single layer including the aforementioned materials. For example, the connection electrode CM may have a multilayer structure of Ti/Al/Ti.

The second organic insulating layer 116 may be disposed on the connection electrode CM. The second organic insulating layer 116 may cover the connection electrode CM. The second organic insulating layer 116 may be formed of the same material as the first organic insulating layer 115 or may be formed of a different material.

A light-emitting diode may be placed on the second organic insulating layer 116. For example, the organic light-emitting diode OLED may be disposed on the second organic insulating layer 116. Alternatively, although not shown, an inorganic light-emitting diode or the like may be disposed on the second organic insulating layer 116.

The organic light-emitting diodes OLEDs may emit red, green, or blue light, or can emit red, green, blue, or white light. The organic light-emitting diode OLED may include a pixel electrode 211, a light-emitting layer 212b, a functional layer 212f, and a counter electrode 213.

The pixel electrode 211 may be disposed on the second organic insulating layer 116. The pixel electrode 211 may be electrically connected to the connection electrode CM through a contact hole defined in the second organic insulating layer 116. The pixel electrode 211 may include a conductive oxide such as indium tin oxide (ITO), indium zinc oxide (IZO), zinc oxide (ZnO), indium oxide (In2O3), indium gallium oxide (IGO), or aluminum zinc oxide (AZO). In an aspect, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In an aspect, the pixel electrode 211 may further include a film formed of ITO, IZO, ZnO or In2O3 above/below the aforementioned reflective film. For example, the pixel electrode 211 may have a multilayer structure of ITO/Ag/ITO.

The pixel definition film 118 may be disposed on the pixel electrode 211. The pixel definition film 118 may include an opening that exposes at least a portion of the pixel electrode 211. The light emission area of light emitted from the organic light-emitting diode OLED may be defined by the opening of the pixel defining film 118. For example, the width of the aperture may correspond to the width of the emitting area.

The pixel definition film 118 may include an organic insulating material. Alternatively, the pixel definition film 118 may include an inorganic insulating material such as silicon nitride, silicon oxynitride, or silicon oxide. Alternatively, the pixel definition film 118 may include an organic insulating material and an inorganic insulating material. In an aspect, the pixel defining film 118 may include a light-blocking material. The light-blocking material may include a resin or paste including carbon black, carbon nanotubes, black dye, metal particles such as nickel, aluminum, molybdenum, or alloys thereof, metal oxide particles (e.g., chromium oxide) or metal nitride particles (e.g., chromium nitride), etc. When the pixel definition film 118 includes a light-blocking material, external light reflection by metal structures arranged under the pixel definition film 118 may be reduced.

The light-emitting layer 212b may be disposed in the opening of the pixel definition film 118. The light-emitting layer 212b may include a polymer or low-molecular organic material that emits light of a predetermined color.

The functional layer 212f may include a first functional layer 212a, an electron transport layer 212c, and an electron injection layer 212d. The first functional layer 212a may include a hole transport layer HTL and/or a hole injection layer HIL. The hole transport layer HTL and/or the hole injection layer HIL may be disposed between the pixel electrode 211 and the light-emitting layer 212b. Specifically, the hole transport layer HTL may be disposed between the light-emitting layer 212b and the hole injection layer HIL. The electron transport layer 212c may be disposed between the light-emitting layer 212b and the electron injection layer 212d. The electron injection layer 212d may be disposed between the electron transport layer 212c and the counter electrode 213. Specifically, the electron injection layer 212d and the counter electrode 213 may be disposed to be in contact with each other. However, at least one of the first functional layer 212a, the electron transport layer 212c, or the electron injection layer 212d may be omitted. Below, a detailed description will be given focusing on the case where the first functional layer 212a, the electron transport layer 212c, and the electron injection layer 212d are respectively disposed.

The first functional layer 212a, the electron transport layer 212c, and/or the electron injection layer 212d may cover the substrate 100 entirely similarly to the counter electrode 213 described below.

When the electron injection layer 212d of the organic light-emitting diode OLED includes ytterbium (Yb) having high light absorption, the light absorption of the electron injection layer 212d may increase, thereby lowering the light transmittance of the display device. To solve this problem, when the amount of ytterbium (Yb) included in the electron injection layer 212d is reduced, the amount of reactive metal (e.g., ytterbium (Yb)) that can capture gas present in the display device may be reduced, which may actually weaken the environmental reliability of the display device.

In an aspect, the electron injection layer 212d of the organic light-emitting diode OLED may include silver (Ag) and lithium (Li). When the electron injection layer 212d includes lithium (Li) having low light absorption, the light absorption of the electron injection layer 212d may be reduced, thereby increasing the light transmittance of the display device. In addition, instead of reducing the concentration of ytterbium (Yb) having high light absorption to increase light transmittance, since the electron injection layer 212d includes lithium (Li), the total amount of reactive metal (e.g., lithium (Li)) capable of capturing gas present in the display device may be maintained, thereby ensuring environmental reliability.

The electron injection layer 212d may include silver (Ag) and lithium (Li). The concentration of lithium (Li) included in the electron injection layer 212d may be 5 vol% or more and 20 vol% or less. When the concentration of lithium (Li) included in the electron injection layer 212d is less than 5 vol%, the efficiency of the electron injection layer 212d may decrease, so that the amount of electrons injected into the light-emitting layer 212b may decrease. In addition, when the concentration of lithium (Li) included in the electron injection layer 212d is less than 5 vol%, the concentration of lithium (Li), a reactive metal that may capture gas present in the display device, is too low, so that pixel shrinkage may occur. When the concentration of lithium (Li) included in the electron injection layer 212d exceeds 20 vol%, the amount of electrons injected into the light-emitting layer 212b may become excessive, which may disrupt the charge balance of the display element and deteriorate the characteristics of the display element, thereby reducing the reliability of the display device.

A thickness d1 of the electron injection layer 212d may be 5 Å or more and 100 Å or less. When the thickness d1 of the electron injection layer 212d is less than 5 Å, the amount of electron injection into the light-emitting layer 212b may decrease, which may reduce the reliability of the display device. When the thickness d1 of the electron injection layer 212d exceeds 100 Å, the light reflectivity may increase and the light transmittance of the display device may decrease.

The counter electrode 213 may be disposed on the functional layer 212f. Specifically, the counter electrode 213 may be disposed on the electron injection layer 212d, and the electron injection layer 212d and the counter electrode 213 may be disposed to be in contact with each other.

The counter electrode 213 may include silver (Ag). In another aspect, the counter electrode 213 may include a silver (Ag)-based alloy. Specifically, the counter electrode 213 may include silver (Ag), palladium (Pd), and copper (Cu). The counter electrode 213 may include 99.1 wt% silver (Ag), 0.1 wt% palladium (Pd), and 0.8 wt% copper (Cu).

When the counter electrode 213 includes silver (Ag) or a silver (Ag)-based alloy, a thickness d2 of the counter electrode 213 may be about 50 Å or more and about 200 Å or less. When the thickness d2 of the counter electrode 213 is less than about 50 Å, the surface resistance of the counter electrode 213 may increase, which may reduce the driving capability of the display element. When the thickness d2 of the counter electrode 213 exceeds about 200 Å, the reflectivity of the counter electrode 213 may increase, so that the light transmittance of the display device may decrease.

In another aspect, the counter electrode 213 may include a conductive oxide. The counter electrode 213 may include at least one of indium tin oxide (ITO), indium zinc oxide (IZO), indium gallium oxide (IGO), or indium gallium zinc oxide (IGZO). When the counter electrode 213 includes a conductive oxide, the thickness d2 of the counter electrode 213 may be about 100 Å or more and about 5000 Å or less.

The thin film encapsulation layer 300 may be disposed on the organic light-emitting diode OLED. The thin film encapsulation layer 300 may cover the organic light-emitting diode OLED. The thin film encapsulation layer 300 may be disposed on the counter electrode 213. In an aspect, the thin film encapsulation layer 300 may include at least one inorganic film layer and at least one organic film layer.

The thin film encapsulation layer 300 may include a first inorganic encapsulation layer 310, an organic encapsulation layer 320, and a second inorganic encapsulation layer 330 that are sequentially laminated. The first inorganic encapsulation layer 310 and the second inorganic encapsulation layer 330 may include one or more inorganic materials selected from aluminum oxide, titanium oxide, tantalum oxide, hafnium oxide, zinc oxide, silicon oxide, silicon nitride, or silicon oxynitride. The first inorganic encapsulation layer 310 and the second inorganic encapsulation layer 330 may be a single layer or multiple layers including the materials described above. The organic encapsulation layer 320 may include a polymer-based material. Polymer-based materials may include acrylic resins, epoxy resins, polyimides, or polyethylene. In an aspect, the organic encapsulating layer 320 may include acrylate.

The touch sensor layer 400 may be disposed on the thin film encapsulation layer 300. The touch sensor layer 400 may include a first touch insulating layer 410, a second touch insulating layer 420, a first conductive layer 430, a third touch insulating layer 440, a second conductive layer 450, and a planarization layer 460.

In an aspect, the first touch insulating layer 410 may be disposed on the second inorganic encapsulation layer 330, and the second touch insulating layer 420 may be disposed on the first touch insulating layer 410. In an aspect, the first touch insulating layer 410 and the second touch insulating layer 420 may include an inorganic insulating material and/or an organic insulating material. For example, the first touch insulating layer 410 and the second touch insulating layer 420 may include an inorganic insulating material such as silicon oxide, silicon nitride, or silicon oxynitride.

In an aspect, at least one of the first touch insulating layer 410 and the second touch insulating layer 420 may be omitted. For example, the first touch insulating layer 410 may be omitted. In this case, the second touch insulating layer 420 may be disposed on the second inorganic encapsulation layer 330, and the first conductive layer 430 may be disposed on the second touch insulating layer 420.

The first conductive layer 430 may be disposed on the second touch insulating layer 420, and the third touch insulating layer 440 may be disposed on the first conductive layer 430. In an aspect, the third touch insulating layer 440 may include an inorganic insulating material and/or an organic insulating material. For example, the third touch insulating layer 440 may include an inorganic insulating material such as silicon oxide, silicon nitride, or silicon oxynitride.

The second conductive layer 450 may be placed on the third touch insulating layer 440. A touch electrode TE of an input sensing layer 48 may be composed with a structure in which the first conductive layer 430 and the second conductive layer 450 are connected. Alternatively, the touch electrode TE may be formed on either the first conductive layer 430 or the second conductive layer 450 and may include a metal line provided in the corresponding conductive layer. The first conductive layer 430 and the second conductive layer 450 may each include at least one of aluminum (Al), copper (Cu), titanium (Ti), molybdenum (Mo), or indium tin oxide (ITO), and may be formed as a single layer or multiple layers including the aforementioned materials. For example, the first conductive layer 430 and the second conductive layer 450 may each have a three-layer structure of titanium layer/aluminum layer/titanium layer.

In an aspect, the planarization layer 460 may cover the second conductive layer 450. The flattening layer 460 may include an organic insulating material.

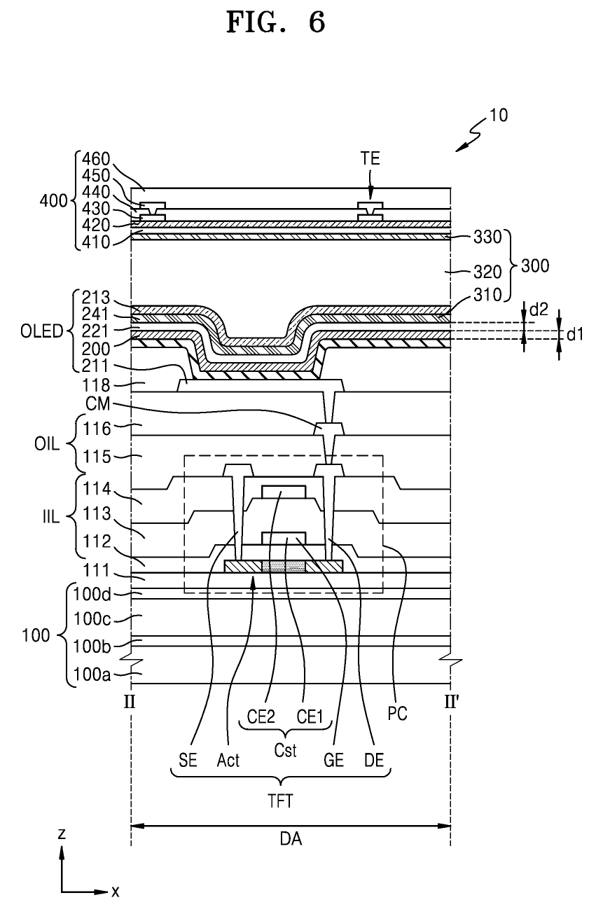

FIG. 6 is a cross-sectional view schematically illustrating a display panel according to an aspect. Specifically, FIG. 6 is a cross-sectional view schematically illustrating a display panel according to an aspect having an organic light-emitting diode of a tandem structure.

Referring to FIG. 6, a hole injection layer 221 may be disposed on the pixel electrode. An intermediate layer 200 may be disposed on the hole injection layer 221. An electron injection layer 241 may be placed on the intermediate layer 200. A counter electrode 213 may be disposed on the electron injection layer 241.

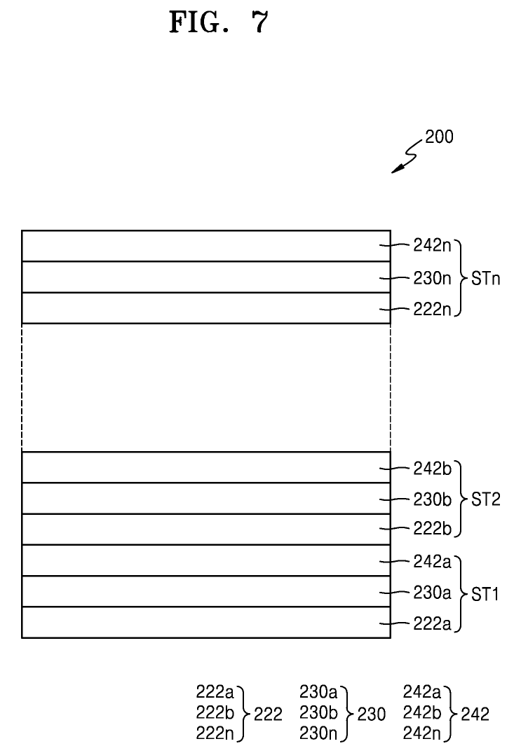

FIG. 7 schematically illustrates a cross-sectional view of the middle layer of an organic light-emitting diode having a tandem structure. Referring to FIG. 7, the intermediate layer 200 of an organic light-emitting diode OLED having a tandem structure may include a plurality of stacks. The plurality of stacks may include a first stack ST1, a second stack ST2, and an nth stack STn. For example, when n is 3, the organic light-emitting diode OLED may include three-layer stacks. As another example, when n is 4, the organic light-emitting diode OLED may include four-layer stacks. As another example, when n is 5, the organic light-emitting diode OLED may include five-layer stacks.

Although not shown in FIG. 7, a charge generation layer CGL may be interposed between each stack. The charge generation layer CGL may include an n-type charge generation layer adjacent to the pixel electrode and a p-type charge generation layer adjacent to the counter electrode 213.

Each stack may include a hole transport layer 222, a light-emitting layer 230, and an electron transport layer 242 sequentially arranged from the pixel electrode. The first stack ST1 may include a first hole transport layer 222a, a first light-emitting layer 230a, and a first electron transport layer 242a disposed in the order adjacent to the pixel electrode, the second stack ST2 may include a second hole transport layer 222b, a second light-emitting layer 230b, and a second electron transport layer 242b disposed in the order adjacent to the pixel electrode, and the nth stack STn may include an nth hole transport layer 222n, an nth light-emitting layer 230n, and an nth electron transport layer 242n disposed in the order adjacent to the pixel electrode.

In an aspect, n in FIG. 7 is 3, and each of the first to third light-emitting layers may emit blue light.

In another aspect, n is 4 in FIG. 7, the first light-emitting layer may emit blue light, the second light-emitting layer may emit blue light, the third light-emitting layer may emit blue light, and the fourth light-emitting layer may emit green light.

In another aspect, n is 5 in FIG. 7, the first light-emitting layer may emit blue light, the second light-emitting layer may emit blue light, the third light-emitting layer may emit green light, the fourth light-emitting layer may emit blue light, and the fifth light-emitting layer may emit green light.

However, the disclosure is not limited thereto. Although not shown, in another aspect, the light-emitting layer 230 of each of the plurality of stacks included in the intermediate layer 200 may be disposed only in the opening of the pixel definition film 118 rather than being fully disposed on the substrate 100.

Referring to FIGS. 6 and 7, because the electron injection layer 241 is disposed on the intermediate layer 200, the electron injection layer 241 and the counter electrode 213 may be disposed to be in contact with each other. However, at least one of the hole injection layer 221, the hole transport layer 222, the electron transport layer 242, or the electron injection layer 241 may be omitted. Below, a detailed description will be given focusing on the case where the hole injection layer 221, the hole transport layer 222, the electron transport layer 242, and the electron injection layer 241 are respectively disposed.

When the electron injection layer 241 of the organic light-emitting diode OLED includes ytterbium (Yb) having high light absorption, the light absorption of the electron injection layer 241 may increase, thereby lowering the light transmittance of the display device. To solve this problem, when the amount of ytterbium (Yb) included in the electron injection layer 241 is reduced, the amount of reactive metal (e.g., ytterbium (Yb)) that may capture gas present in the display device may be reduced, which may actually weaken the environmental reliability of the display device.

In an aspect, the electron injection layer 241 of the organic light-emitting diode OLED may include silver (Ag) and lithium (Li). When the electron injection layer 241 includes lithium (Li) having low light absorption, the light absorption of the electron injection layer 241 may be reduced, thereby increasing the light transmittance of the display device. In addition, instead of reducing the concentration of ytterbium (Yb) with high light absorption to increase light transmittance, because the electron injection layer 241 includes lithium (Li), the total amount of reactive metal (e.g., lithium (Li)) that may capture gas present in the display device may be maintained, thereby ensuring environmental reliability.

The electron injection layer 241 may include silver (Ag) and lithium (Li). The concentration of lithium (Li) included in the electron injection layer 241 may be 5 vol% or more and 20 vol% or less. When the concentration of lithium (Li) included in the electron injection layer 241 is less than 5 vol%, the efficiency of the electron injection layer 241 may decrease, so that the amounts of electrons injected into the light-emitting layer 230 may decrease. In addition, when the concentration of lithium (Li) included in the electron injection layer 241 is less than 5 vol%, the concentration of lithium (Li), a reactive metal that may capture gas present in the display device, may be too low, so pixel shrinkage may occur. When the concentration of lithium (Li) included in the electron injection layer 241 exceeds 20 vol%, the amounts of electrons injected into the light-emitting layer 230 may become excessive, which may disrupt the charge balance of the display element and deteriorate the characteristics of the display element, thereby reducing the reliability of the display device.

The thickness d1 of the electron injection layer 241 may be 5 Å or more and 100 Å or less. When the thickness d1 of the electron injection layer 241 is less than 5 Å, the amount of electron injection into the light-emitting layer 230 may decrease, which may reduce the reliability of the display device. When the thickness d1 of the electron injection layer 241 exceeds 100 Å, the light reflectivity may increase and the light transmittance of the display device may decrease.

The counter electrode 213 may be disposed on the electron injection layer 241. The electron injection layer 241 and the counter electrode 213 may be disposed to be in contact with each other.

The counter electrode 213 may include silver (Ag). In another aspect, the counter electrode 213 may include a silver (Ag)-based alloy. Specifically, the counter electrode 213 may include silver (Ag), palladium (Pd), and copper (Cu). The counter electrode 213 may include 99.1 wt% silver (Ag), 0.1 wt% palladium (Pd), and 0.8 wt% copper (Cu).

When the counter electrode 213 includes silver (Ag) or a silver (Ag)-based alloy, the thickness d2 of the counter electrode 213 may be about 50 Å or more and about 200 Å or less. When the thickness d2 of the counter electrode 213 is less than about 50 Å, the surface resistance of the counter electrode 213 may increase, which may reduce the driving capability of the display element. When the thickness d2 of the counter electrode 213 exceeds about 200 Å, the reflectivity of the counter electrode 213 may increase, so that the light transmittance of the display device may decrease.

In another aspect, the counter electrode 213 may include a conductive oxide. The counter electrode 213 may include at least one of indium tin oxide (ITO), indium zinc oxide (IZO), indium gallium oxide (IGO), or indium gallium zinc oxide (IGZO). When the counter electrode 213 includes a conductive oxide, the thickness d2 of the counter electrode 213 may be about 100 Å or more and about 5000 Å or less.

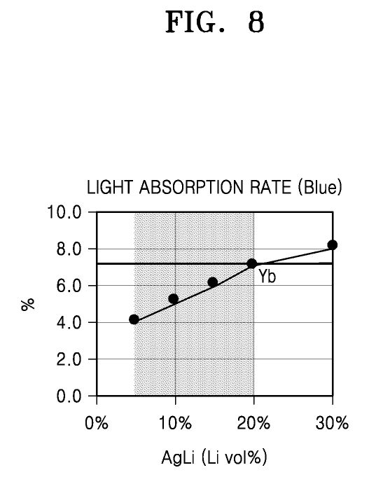

FIG. 8 is a graph schematically showing the light absorption rate according to the concentration of lithium (Li) when the electron injection layer includes silver (Ag) and lithium (Li), compared to the light absorption rate when the electron injection layer includes ytterbium (Yb). When the electron injection layer includes ytterbium (Yb), the counter electrode may include silver (Ag) and magnesium (Mg). Additionally, when the electron injection layer includes silver (Ag) and lithium (Li), the counter electrode may include silver (Ag) without including magnesium (Mg).

Referring to FIG. 8, the light absorption rate of the electron injection layer including silver (Ag) and lithium (Li) and including a lithium (Li) concentration of 5 vol% or more and 20 vol% or less may be less than the light absorption rate of the electron injection layer including ytterbium (Yb).

When the electron injection layer includes lithium (Li), which is a low light absorption material, and the lithium (Li) concentration is 5 vol% or more and 20 vol% or less, the light absorption rate of the electron injection layer may be lower than when the electron injection layer includes ytterbium (Yb), which is a high light absorption material. As the light absorption rate of the electron injection layer decreases, the light transmittance of the display device may increase, and the reliability and efficiency of the display device may be increased.

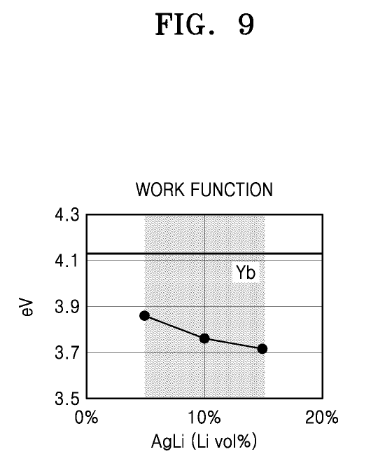

FIG. 9 is a graph schematically showing the work function according to the concentration of lithium (Li) when the electron injection layer includes silver (Ag) and lithium (Li), compared to the work function when the electron injection layer includes ytterbium (Yb). When the electron injection layer includes ytterbium (Yb), the counter electrode may include silver (Ag) and magnesium (Mg). Additionally, when the electron injection layer includes silver (Ag) and lithium (Li), the counter electrode may include silver (Ag) without including magnesium (Mg).

Referring to FIG. 9, the work function of the electron injection layer (241, see FIG. 6a) including silver (Ag) and lithium (Li) may be smaller than the work function of the electron injection layer including ytterbium (Yb), regardless of the concentration of lithium (Li). The work function of the electron injection layer including lithium (Li) may be smaller than the work function of the electron injection layer including ytterbium (Yb), so that electron injection into the light-emitting layer may be smoother, and the reliability and efficiency of the display device may be increased.

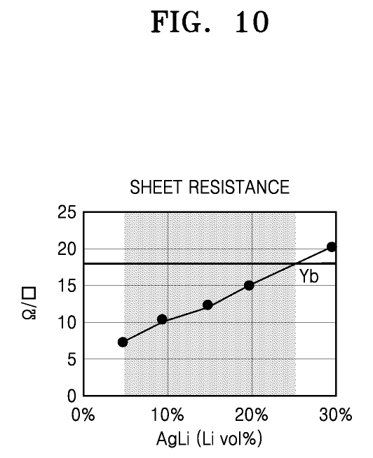

FIG. 10 is a graph schematically showing the sheet resistance according to the concentration of lithium (Li) when the electron injection layer includes silver (Ag) and lithium (Li), compared to the sheet resistance when the electron injection layer includes ytterbium (Yb). When the electron injection layer includes ytterbium (Yb), the counter electrode may include silver (Ag) and magnesium (Mg). Additionally, when the electron injection layer includes silver (Ag) and lithium (Li), the counter electrode may include silver (Ag) without including magnesium (Mg). Referring to FIG. 10, the sheet resistance of an electron injection layer including silver (Ag) and lithium (Li) and having a lithium (Li) concentration of 5 vol% or more and 20 vol% or less may be smaller than the sheet resistance of an electron injection layer including ytterbium (Yb). As the surface resistance of the electron injection layer decreases, the electrical characteristics of the display device improve, which may increase the efficiency and reliability of the display device.

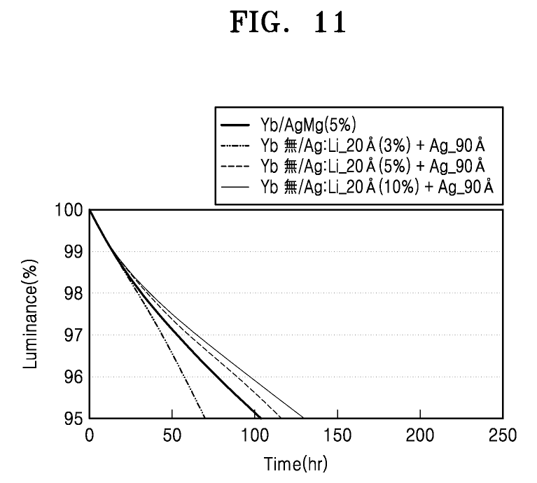

FIG. 11 schematically shows the luminance of the display device over time for cases where the electron injection layer includes ytterbium (Yb) and for cases where the electron injection layer includes silver (Ag) and lithium (Li) at different concentrations. When the electron injection layer includes ytterbium (Yb), the counter electrode may include silver (Ag) and magnesium (Mg). Additionally, when the electron injection layer includes silver (Ag) and lithium (Li), the counter electrode may include silver (Ag) without including magnesium (Mg).

Referring to FIG. 11, it may be confirmed that when the electron injection layer includes ytterbium (Yb), it takes about 100 hours for the brightness of the display device to reach 95% of the initial level. When the electron injection layer includes silver (Ag) and lithium (Li) and includes 3 vol% lithium (Li), it may be confirmed that it takes less than 100 hours for the brightness of the display device to reach 95% of the initial comparison. When the electron injection layer includes silver (Ag) and lithium (Li) and includes 5 vol% or 10 vol% lithium (Li), it may be confirmed that it takes more than 100 hours for the brightness of the display device to reach 95% of the initial comparison.

When the electron injection layer includes silver (Ag) and lithium (Li) and includes more than 5 vol% lithium, the time required for the luminance to reach 95% of the initial value may be longer than when the electron injection layer includes ytterbium (Yb). In other words, when the electron injection layer includes silver (Ag) and lithium (Li) and includes lithium at 5 vol% or more, the stability and lifespan of the display device may be improved compared to when the electron injection layer includes ytterbium (Yb).

In an aspect, the electron injection layer (212d, see FIG. 5) of an organic light-emitting diode (OLED) may include lithium (Li), which has low light absorption, in a concentration of 5 vol% or more and 20 vol% or less, instead of ytterbium (Yb) or magnesium (Mg), which has high light absorption, so that the light transmittance of the display device may increase. Because lithium (Li) is included instead of ytterbium (Yb), a reactive metal, to increase the light transmittance of the display device, the total amount of reactive metal included in the electron injection layer is maintained, so that the environmental reliability of the display device may be secured.

According to aspects of the present disclosure described above, a display device with improved reliability and quality may be implemented. Of course, the scope of the disclosure is not limited by these effects.

Although the disclosure has been described with reference to the aspects shown in the drawings, these are merely exemplary aspects of the present disclosure, and those skilled in the art will understand that various modifications and equivalents are possible therefrom. Therefore, the true technical protection scope of the disclosure should be determined by the technical idea of the attached claims.

What is claimed is:

1. A display panel, comprising:
a substrate;
a pixel electrode on the substrate;
an electron injection layer on the pixel electrode, the electron injection layer comprising silver (Ag) and lithium (Li); and
a counter electrode on the electron injection layer;
wherein a concentration of lithium (Li) in the electron injection layer is 5 vol% or more and 20 vol% or less.

2. The display panel of claim 1, wherein
a thickness of the electron injection layer is 5 Å or more and 100 Å or less.

3. The display panel of claim 1, wherein
the counter electrode comprises silver (Ag).

4. The display panel of claim 3, wherein
a thickness of the counter electrode is 50 Å or more and 200 Å or less.

5. The display panel of claim 1, wherein
the counter electrode comprises a silver (Ag) alloy.

6. The display panel of claim 5, wherein
the silver (Ag) alloy comprises silver (Ag), palladium (Pd), and copper (Cu).

7. The display panel of claim 5, wherein
a thickness of the counter electrode is 50 Å or more and 200 Å or less.

8. The display panel of claim 1, wherein
the counter electrode comprises a conductive oxide,

9. The display panel of claim 8, wherein
the counter electrode comprises at least one of indium tin oxide (ITO), indium zinc oxide (IZO), indium gallium oxide (IGO), or indium gallium zinc oxide (IGZO).

10. The display panel of claim 8, wherein
a thickness of the counter electrode is 100 Å or more and 5000 Å or less.

11. An electronic device, comprising:
a display panel; and
a lower cover comprising a front surface, wherein the front surface comprises an opening configured to expose at least a portion of the display panel, and wherein the lower cover is at least a portion of an exterior of the electronic device,
wherein the display panel comprises:
a substrate;
a pixel electrode on the substrate;
an electron injection layer on the pixel electrode, the electron injection layer comprising silver (Ag) and lithium (Li); and
a counter electrode on the electron injection layer;
wherein a concentration of lithium (Li) in the electron injection layer is 5 vol% or more and 20 vol% or less.

12. The electronic device of claim 11, wherein
a hole injection layer is on the pixel electrode; and
an intermediate layer disposed is on the hole injection layer;

13. The electronic device of claim 12, wherein
the intermediate layer includes a plurality of stacked layers,
and each of the plurality of stacked layers includes a hole transport layer, an emitting layer, and an electron transport layer.

14. The electronic device of claim 11, wherein
a thickness of the electron injection layer is 5 Å or more and 100 Å or less.

15. The electronic device of claim 11, wherein
the counter electrode comprises silver (Ag).

16. The electronic device of claim 15, wherein
a thickness of the counter electrode is 50 Å or more and 200 Å or less.

17. The electronic device of claim 11, wherein
the counter electrode comprises a silver (Ag) alloy, and
a thickness of the counter electrode is 50 Å or more and 200 Å or less.

18. The electronic device of claim 17, wherein
the silver (Ag) alloy comprises silver (Ag), palladium (Pd), and copper (Cu).

19. The electronic device of claim 11, wherein
the counter electrode comprises a conductive oxide, and
a thickness of the counter electrode is 100 Å or more and 5000 Å or less.

20. The electronic device of claim 19, wherein
the counter electrode includes at least one of indium tin oxide (ITO), indium zinc oxide (IZO), indium gallium oxide (IGO), or indium gallium zinc oxide (IGZO).
